(19) United States
(12) Patent Application Publication
(10) Pub. No.: US 2020/0313069 A1
(43) Pub. Date: Oct. 1, 2020

(54) MULTILAYER PIEZOELECTRIC ELEMENT

(71) Applicant: TDK CORPORATION, Tokyo (JP)

(72) Inventors: Makoto ISHIZAKI, Tokyo (JP); Masaharu HIRAKAWA, Tokyo (JP)

(73) Assignee: TDK CORPORATION, Tokyo (JP)

(21) Appl. No.: 16/829,010

(22) Filed: Mar. 25, 2020

(30) Foreign Application Priority Data
Mar. 28, 2019 (JP) 2019-064827

(51) Int. Cl. H01L 41/083; H01L 41/047; H01L 41/273

(52) U.S. Cl. CPC H01L 41/0838; H01L 41/273; H01L 41/0471

(57) ABSTRACT

A multilayer piezoelectric element includes a laminated body and a lateral electrode. The laminated body includes a piezoelectric layer and an internal electrode layer. The piezoelectric layer is formed along a plane including a first axis and a second axis perpendicular to each other. The internal electrode layer is laminated on the piezoelectric layer. The internal electrode layer has a leading portion exposed to the lateral surface of the laminated body and is electrically connected with the lateral electrode via the leading portion. Ro is higher than Rc in the the laminated body. Ro is an existence rate of outer circumferential pores existing in the piezoelectric layer located in an outer circumferential part of the internal electrode layer. Rc is an existence rate of central pores existing in a central part of the laminated body.

### BACKGROUND OF THE INVENTION

The present invention relates to a multilayer piezoelectric element.

Multilayer piezoelectric elements have a structure in which internal electrodes and piezoelectric layers are laminated and can increase displacement amount and driving force per unit volume compared to non-multilayer piezoelectric elements. In the multilayer piezoelectric elements, cracks may be generated in an interface between the internal electrodes and the piezoelectric layers due to the stress generated in the laminated body. The generation of cracks in the laminated body deteriorates characteristics (e.g., displacement amount) of the piezoelectric element. Thus, a technique of preventing the generation of cracks is required.

For example, Patent Document 1 discloses a technique of preventing the generation of cracks in the piezoelectric layers during manufacture by forming a dummy electrode around the internal electrode layer. However, the technique disclosed by Patent Document 1 may be unable to sufficiently prevent the generation of cracks when the piezoelectric layers are thin, when the lamination number is large, when the element body is large, or the like.

Patent Document 1: JP3794292 (B2)

### BRIEF SUMMARY OF INVENTION

The present invention has been achieved under such circumstances. It is an object of the invention to provide a multilayer piezoelectric element capable of preventing generation of cracks.

To achieve the above object, a multilayer piezoelectric element according to the present invention includes:

a laminated body including:
a piezoelectric layer formed along a plane including a first axis and a second axis perpendicular to each other; and
an internal electrode layer laminated on the piezoelectric layer; and

a lateral electrode formed on a lateral surface of the laminated body perpendicular to the first axis,

wherein the internal electrode layer has a leading portion exposed to the lateral surface of the laminated body and is electrically connected with the lateral electrode via the leading portion, and

wherein Ro is higher than Rc in the the laminated body, in which Ro is an existence rate of outer circumferential pores existing in the piezoelectric layer located in an outer circumferential part of the internal electrode layer, and Rc is an existence rate of central pores existing in a central part of the laminated body.

In the multilayer piezoelectric element according to the present invention, there are fewer pores (central pores) in the central part of the laminated body. Meanwhile, the existence rate of pores (outer circumferential pores) is high in the piezoelectric layer located in the outer circumferential part of the internal electrode layer. In the present invention, this structure allows the outer circumferential pores to reduce the shrinkage stress in the laminated body. Thus, even if the laminated body is thinner or larger, the generation of cracks is prevented, and characteristics (e.g., deformation) of the multilayer piezoelectric element can be improved.

Preferably, a difference (Ro−Rc) between Ro and Rc is 2% or more and 15% or less in the laminated body. More preferably, a difference (Ro−Rc) between Ro and Rc is 3% or more and 8% or less in the laminated body. When the difference in existence rate between the outer circumferential pores and the central pores is within the above range, characteristics (e.g., deformation) of the multilayer piezoelectric element can further be improved.

Preferably, a dummy electrode layer is formed with a gap to surround the outer circumferential part of the internal electrode layer excluding the leading portion on the plane of the piezoelectric layer. Preferably, gap pores are formed in the piezoelectric layer located in the gap between the internal electrode layer and the dummy electrode layer in the laminated body.

When the gap pores are present, the multilayer piezoelectric element according to the present invention can prevent the change of the composition of the piezoelectric layer and obtain a high piezoelectric constant.

Preferably, an existence rate of the gap pores in the piezoelectric layer located in the gap is 3% or more and 20% or less.

Preferably, the gap has a width of 0.05 mm or more and 0.2 mm or less.

Preferably, the gap pores have an average size of 0.04 μm or more and 0.18 μm or less.

The multilayer piezoelectric element according to the present invention can be utilized as a conversion element from electrical energy to mechanical energy. For example, the multilayer piezoelectric element according to the present invention is applicable to piezoelectric actuators, piezoelectric buzzers, piezoelectric sounders, ultrasonic motors, speakers, etc. and is particularly favorably utilized as piezoelectric actuators. Specifically, the piezoelectric actuators are utilized for haptic devices, lens driving, HDD head driving, inkjet printer head driving, fuel injection valve driving, etc.

### BRIEF DESCRIPTION OF DRAWINGS

FIG. 1 is a schematic perspective view illustrating a multilayer piezoelectric element according to an embodiment of the present invention.

FIG. 2 is a schematic cross-sectional view cut along the II-II line shown in FIG. 1.

FIG. 3A is a schematic cross-sectional view cut along the line shown in FIG. 1.

FIG. 3B is a schematic perspective view of a multilayer piezoelectric element according to another embodiment.

FIG. 4A is a plane view illustrating an electrode pattern contained in the multilayer piezoelectric element shown in FIG. 3A.

FIG. 4B is a plane view illustrating an electrode pattern contained in the multilayer piezoelectric element shown in FIG. 3B.

FIG. 5 is an exploded perspective view of the multilayer piezoelectric element shown in FIG. 1.

FIG. 6 is a schematically enlarged cross-sectional view of the region VI shown in FIG. 3A and FIG. 3B.

FIG. 7A is a schematically enlarged cross-sectional view of the region VIIA shown in FIG. 3A.

FIG. 7B is a schematically enlarged cross-sectional view of the region VIIB shown in FIG. 3B.

### DETAILED DESCRIPTION OF INVENTION

Hereinafter, the present invention is explained based on embodiments shown in the figures.

### First Embodiment

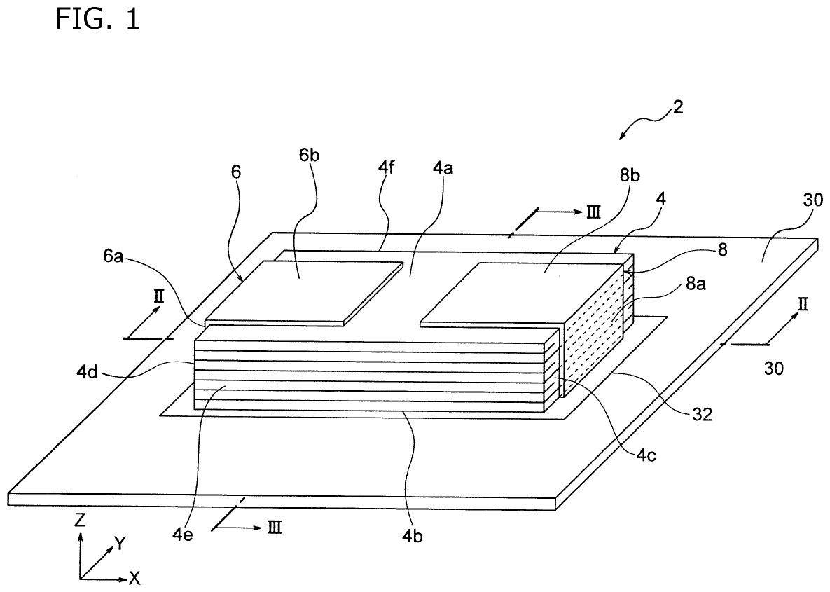

FIG. 1 is a schematic perspective view of a vibration device according to the present embodiment. As shown in FIG. 1, a multilayer piezoelectric element 2 is bonded on a vibration plate 30 via an adhesive layer 32. The multilayer piezoelectric element 2 is formed from a laminated body 4, a first external electrode 6, and a second external electrode 8.

The laminated body 4 has a substantially rectangular parallelepiped shape and has a front surface 4a and a back surface 4b substantially perpendicular to the Z-axis direction, lateral surfaces 4c and 4d substantially perpendicular to the X-axis (first axis) direction, and lateral surfaces 4e and 4f substantially perpendicular to the Y-axis (second axis) direction. Incidentally, insulating protect layers (not illustrated) may be formed on the lateral surfaces 4c-4f of the laminated body 4 excluding areas on which the external electrodes 6 and 8 are formed. In the figures, the X-axis, the Y-axis, and the Z-axis are substantially perpendicular to each other.

The first external electrode 6 has a first lateral part 6a formed along the lateral surface 4d of the laminated body 4 and a first surface part 6b formed along the front surface 4a of the laminated body 4. The first lateral part 6a and the first surface part 6b have a substantially rectangular shape and are connected with each other at their intersection. Incidentally, the first lateral part 6a and the first surface part 6b are illustrated separately in the figures, but are actually formed integrally.

The second external electrode 8 is formed similarly to the first external electrode 6. That is, the second external electrode 8 has a second lateral part 8a formed along the lateral surface 4c of the laminated body 4 and a second surface part 8b formed along the front surface 4a of the laminated body 4. The second lateral part 8a and the second surface part 8b are connected with each other at their intersection. Incidentally, the first surface part 6b and the second surface part 8b are formed separately and insulated electrically from each other.

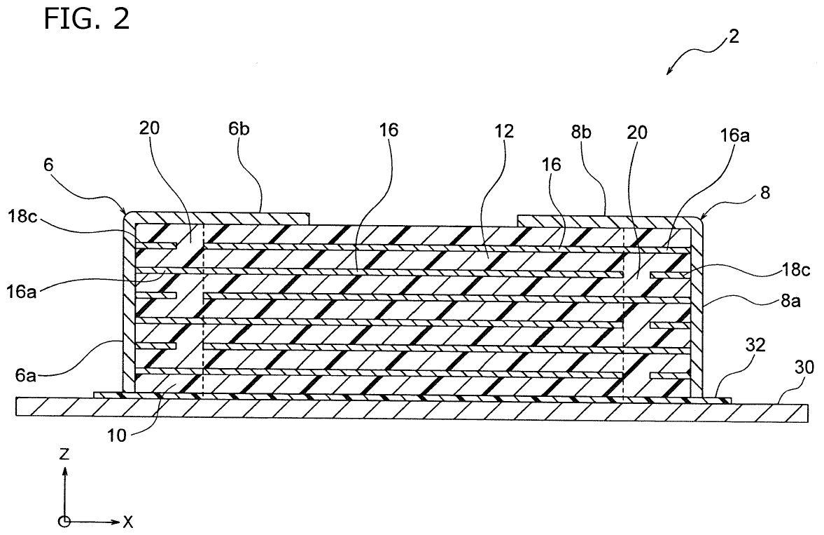

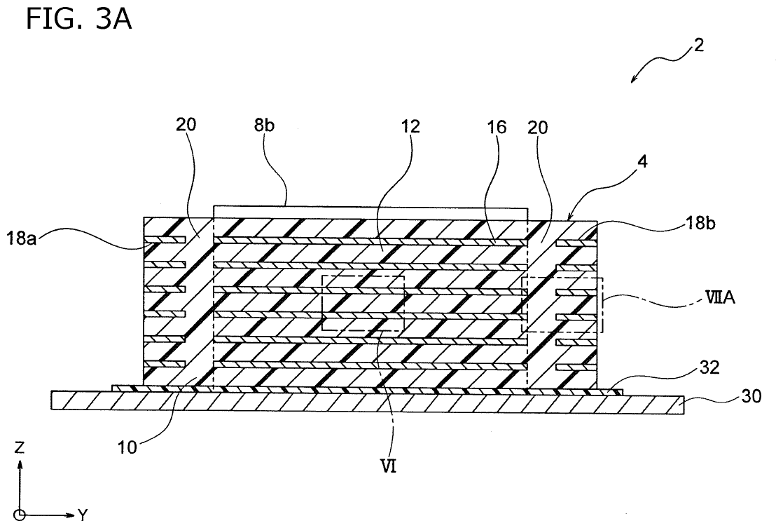

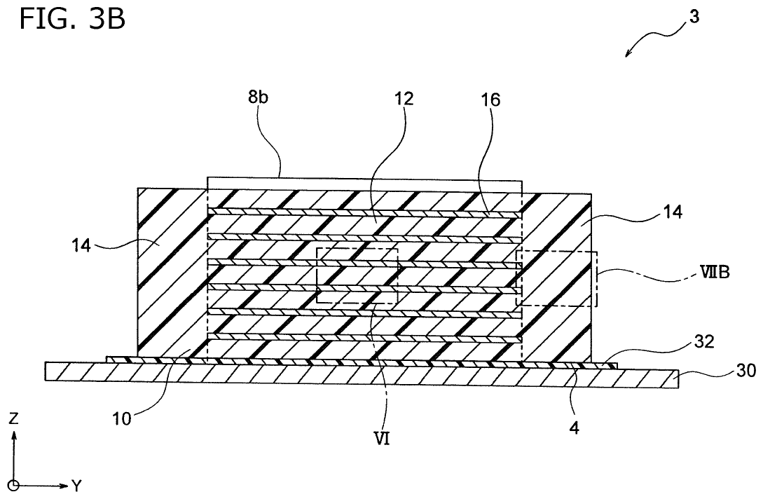

As shown in FIG. 2 and FIG. 3A, the laminated body 4 has an internal structure in which piezoelectric layers 10 and internal electrode layers 16 are alternately laminated in the lamination direction (Z-axis direction). The internal electrode layers 16 are laminated so that leading portions 16a are alternately exposed to the lateral surface 4c or 4d of the laminated body 4. At the leading portions 16a, the internal electrode layers 16 are electrically connected with the first external electrode 6 or the second external electrode 8.

In the present embodiment, the piezoelectric layers 10 at a central part of the laminated body 4 have piezoelectric active parts 12 sandwiched by the internal electrode layers 16. That is, the piezoelectric active parts 12 are a region surrounded by the dotted line shown in FIG. 2 and FIG. 3. In this region, a mechanical displacement is caused by voltage application via the first external electrode 6 and the second external electrode 8 having different polarities.

The internal electrode layers 16 are composed of any conductive material, such as a noble metal (e.g., Ag, Pd, Au, Pt), an alloy of these metals (e.g., Ag—Pd), a base metal (e.g., Cu, Ni), and an alloy of these metals.

The first external electrode 6 and the second external electrode 8 are also composed of a conductive material, such as a material similar to the conductive material constituting the internal electrodes. The first external electrode 6 and the second external electrode 8 may be formed by mixing a conductive metal powder (e.g., Ag, Cu) and a glass powder (e.g., SiO₂) and firing this mixture. Incidentally, a plating layer or a sputtered layer containing the above-mentioned various metals may further be formed on the exteriors of the first external electrode 6 and the second external electrode 8.

The piezoelectric layers 10 are made of any material that exhibits piezoelectric effect or inverse piezoelectric effect, such as PbZrₓTi₁₋ₓO₃ (PZT), BaTiO3 (BT), BiNaTiO₃ (BNT), BiFeO₃ (BFO), (Bi₂O₂)²⁺(Aₘ₋₁BₘO₃ₘ₊₁)²⁻ (BLSF), and (K, Na)NbO₃ (KNN). To improve characteristics, the piezoelectric layers 10 may contain a sub-component. The amount of the sub-component is determined based on desired characteristics.

Incidentally, the piezoelectric layers 10 have any thickness, but preferably have a thickness of about 0.5 to 100 μm in the present embodiment. Likewise, the internal electrode layers 16 have any thickness, but preferably have a thickness of about 0.5 to 2.0 μm. As shown in FIG. 2 and FIG. 3A, the piezoelectric layers 10 are arranged on the front surface 4a and the back surface 4b of the laminated body 4.

In the present embodiment, the vibration plate 30 is used for amplifying the vibration of the multilayer piezoelectric element 2. The vibration plate 30 is made of any elastic material, such as a metal material of Ni, Ni—Fe alloy, brass, and stainless steel. The vibration plate 30 has any thickness and size that are determined appropriately based on the usage of the multilayer piezoelectric element 2. For example, the vibration plate 30 can have a thickness of 0.1 mm to 0.5 mm and a length in the X-axis direction or in the Y-axis direction that is about one to three times larger than the element body in plane view.

As mentioned above, the multilayer piezoelectric element 2 is bonded on the vibration plate 30 via the adhesive layer 32. The adhesive layer 32 is made of, for example, a bonding material (e.g., epoxy resin, acrylic resin, silicone resin, butyral resin), but preferably has electrical insulation without containing a conductive filler. When the adhesive layer 32 has electrical insulation, there is no short circuit between the first external electrode 6 and the second external electrode 8 even if the vibration plate 30 is made of metal.

Preferably, the adhesive layer 32 has a thickness of 10 μm to 1000 μm. When the adhesive layer 32 has such a thickness, the vibration generated from the multilayer piezoelectric element 2 can effectively transmit to the vibration plate 30 while maintaining the adhesion between the multilayer piezoelectric element 2 and the vibration plate 30.

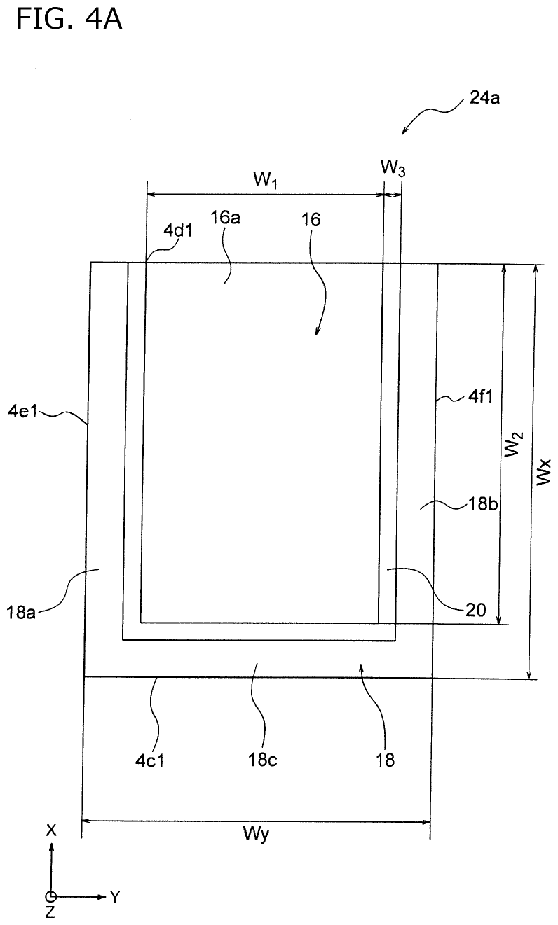

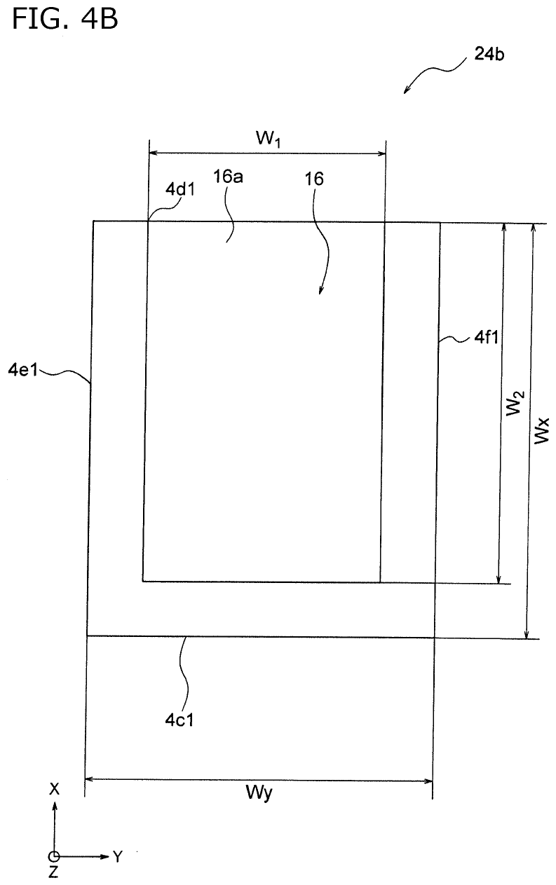

FIG. 4A is a schematic plane view of an electrode pattern 24a contained in the laminated body 4. The piezoelectric layers 10 are located along a plane including the X-axis and the Y-axis at the lower side of the Z-axis direction shown in FIG. 4A. Each of the piezoelectric layers 10 has sides 4c1 to 4f1 corresponding to the lateral surfaces 4c to 4f of the laminated body 4 (see FIG. 1). Then, the electrode pattern 24a formed from the internal electrode layer 16 and a dummy electrode layer 18 is laminated on the surface of the piezoelectric layer 10.

In the electrode pattern 24a shown in FIG. 4A, the internal electrode layer 16 has the leading portion 16a exposed to the side 4d1. The dummy electrode layer 18 is formed with a gap 20 to surround the internal electrode layer 16 excluding the leading portion 16a. Thus, the internal electrode layer 16 and the dummy electrode layer 18 are insulated electrically. In the present embodiment, the gap 20 has a width W3 of 0.03 mm or more and 0.3 mm or less (preferably, 0.05 mm or more and 0.2 mm or less).

In the present embodiment, the outer circumference of the dummy electrode layer 18 is exposed to the lateral surfaces 4c to 4f of the laminated body 4 and has a first lateral pattern 18a along the side 4e1, a second lateral pattern 18b along the side 4f1, and a joint pattern 18c along the side 4c1. The joint pattern 18c is located opposite to the leading portion 16a and joints the two lateral patterns 18a and 18b.

In the present embodiment, the first lateral part 6a of the first external electrode 6 is formed to have a width that is equal to or smaller than a width W1 of the internal electrode layers 16 in the Y-axis direction, and the dummy electrode layer 18 and the first lateral part 6a are not connected with each other. That is, the dummy electrode layer 18 is electrically insulated with the internal electrode layer 16 and the external electrodes 6 and 8 and does not contribute to appearance of piezoelectric characteristics. Since the first lateral part 6a and the second lateral part 8a are formed in such a manner, the first external electrode 6 and the second external electrode 8 are not short-circuited via the dummy electrode layer 18.

To secure the electric insulation between the first external electrode 6 and the second external electrode 8, a slit may be formed on the lateral pattern 18a (18b) of the dummy electrode layer 18, or the dummy electrode layer 18 may be formed so that the end of the lateral pattern 18a (18b) is not exposed to the side 4d1. In this case, the first lateral part 6a of the first external electrode 6 can have a width that is similar to a width Wy of the piezoelectric layers 10 in the Y-axis direction.

In the present embodiment, the dummy electrode layers 18 are preferably configured so that the difference in thermal shrinkage behavior between the dummy electrode layers 18 and the internal electrode layers 16 is smaller than that between the internal electrode layers 16 and the piezoelectric layers 10. Preferably, the dummy electrode layers 18 contain a conductive metal. The dummy electrode layers 18 and the internal electrode layers 16 may be made of the same material or different materials.

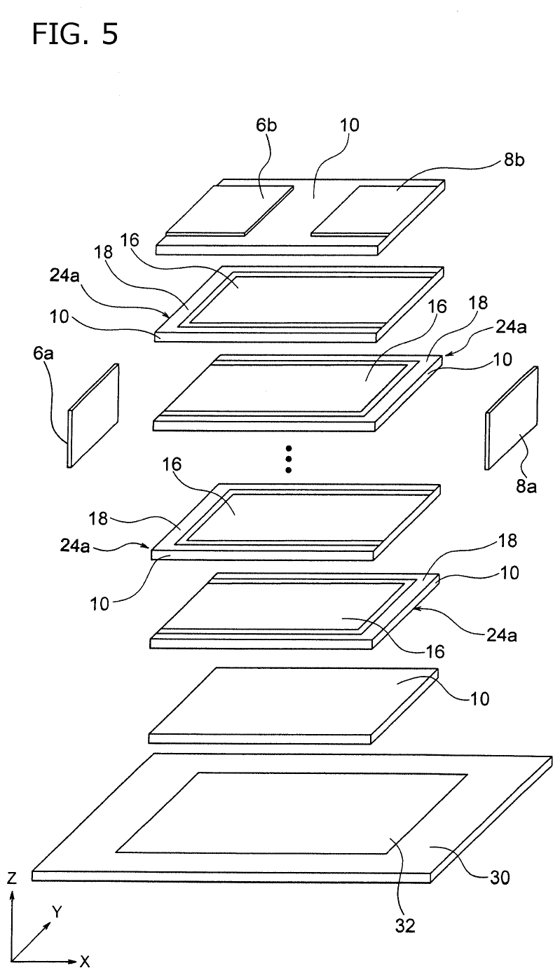

FIG. 5 is an exploded perspective view of the multilayer piezoelectric element 2 according to the present embodiment. As shown in FIG. 5, when the piezoelectric layers 10 are laminated by three or more layers, the electrode patterns 24a are preferably laminated with the orientation changed every layer. Specifically, the electrode patterns 24a after the second layer are laminated by rotating every layer at 180 degrees around the Z-axis. Thus, the leading portions 16a of the internal electrode layers 16 are exposed alternately to the side 4c1 and the side 4d1 and connected to the first lateral part 6a or the second lateral part 8a.

When a plurality of piezoelectric layers 10 and electrode patterns 24a is laminated as shown in FIG. 5, the displacement amount, the driving force, and the like can be increased compared to those of non-multilayer piezoelectric elements. In the present embodiment, the lamination number of piezoelectric layers 10 is two or more and has no upper limit, but is preferably about 3 to 20. The lamination number of piezoelectric layers 10 is appropriately determined based on the purpose of the multilayer piezoelectric element 2.

In the present embodiment, multiple pores 22 are formed on the piezoelectric layers 10 in the laminated body 4. The existence rate of the pores 22 changes depending upon the location in the laminated body.

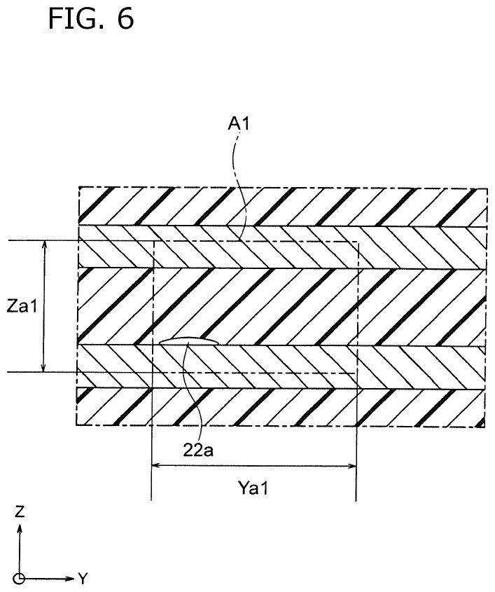

FIG. 6 is a schematically enlarged cross-sectional view of the region VI corresponding to a central part of the laminated body 4 shown in FIG. 3A. As shown in FIG. 6, pores are hardly formed in the central part of the laminated body 4. The piezoelectric layers 10 and the internal electrode layers 16 are conceivably densely laminated. However, bubble may slightly be present in the lamination of green sheets in the following manufacturing process, and central pores 22a are formed by the bubble. Since the central part of the laminated body 4 corresponds to the piezoelectric active parts 12, the existence rate of the central pores 22a is preferably smaller. Specifically, the existence rate of the central pores 22a is 10% or less or may be 0% on a predetermined cross-sectional area.

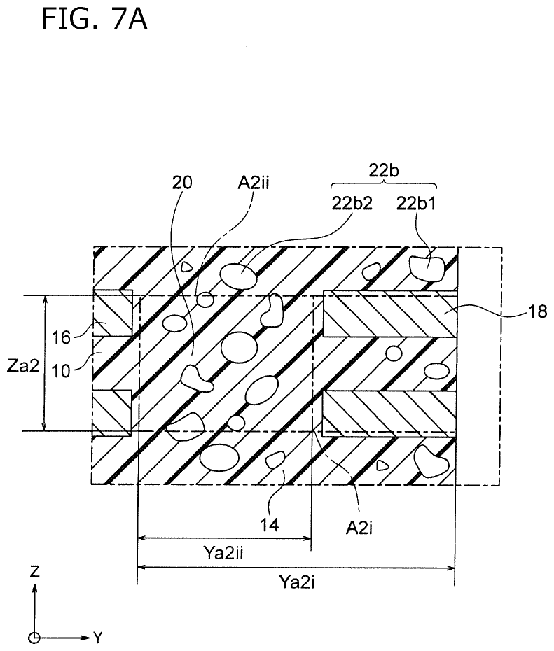

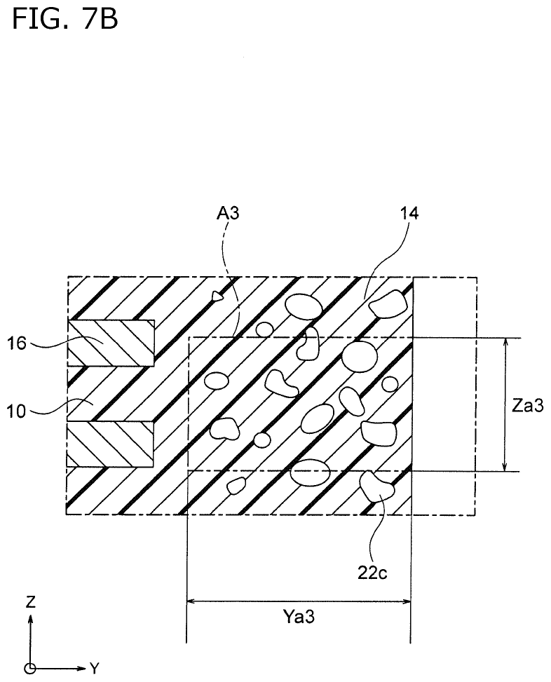

Meanwhile, FIG. 7A is a schematically enlarged cross-sectional view of the region VIIA corresponding to an outer circumferential part 14 of the internal electrode layer 16 shown in FIG. 3A. As shown in FIG. 7A, outer circumferential pores 22b are formed in the outer circumferential part 14 of the internal electrode layer 16. The outer circumferential pores 22b can be classified into dummy-electrode pores 22b1 formed between the dummy electrode layers 18 and gap pores 22b2 formed in the gap 20.

In the present embodiment, Ro is higher than Rc, where Ro is an existence rate of the outer circumferential pores 22b positioned in the outer circumferential part 14 of the internal electrode layer 16, and Rc is an existence rate of the central pores 22a. In the outer circumferential part of the internal electrode layer 16, the existence rate of the gap pores 22b2 tends to be higher than that of the dummy-electrode pores 22b1. Preferably, the pores 22a (22b) have an average size of 0.04 μm or more and 0.2 μm or less (more preferably, 0.04 μm or more and 0.18 μm or less).

In the present embodiment, “the existence rate Ro is higher than the existence rate Rc” means that the difference (Ro−Rc) in existence rate is 2% or more considering the effects of measurement errors. The respective pores 22a and 22b can actually be measured by observing a cross section of the laminated body 4 with FE-SEM or so. In the present embodiment, an existence rate and a pore size of the pores 22a (22b) are defined in the following manner.

Before the existence rate and the pore size of the pores are analyzed, at least 10 analysis regions A are initially selected by observing a cross section of the laminated body 4 with a FE-SEM. When the central pores 22a are analyzed, 10 or more analysis regions A1 (Ya1×Za1) as shown in FIG. 6 are selected at an approximately central position of the laminated body 4 (i.e., a position that is approximately central in any of the X-axis direction, the Y-axis direction, and the Z-axis direction). In the analysis of the central pores 22a, a cross section to be analyzed may be an X-Z cross section (FIG. 2) or a Y-Z cross section (FIG. 3A).

When the outer circumferential pores 22b are analyzed, a Y-Z cross section is taken, and 10 or more analysis regions A2i (Ya2i× Za2) are selected in the outer circumferential part 14 of the internal electrode layer 16 and at an approximately central part in the X-axis direction and the Z-axis direction. In particular, when the existence rate of the gap pores 22b2 in the gap 20 is analyzed, 10 or more analysis regions A2ii (Ya2ii×Za2) are selected in an approximately central position of the gap 20 in the Y-axis direction and in the Z-axis direction. Incidentally, the size of each of the analysis regions A1, A2i, and A2ii is appropriately determined based on observation simplicity and accuracy.

The existence rate and the pore size of the pores are calculated by incorporating the above-taken cross-sectional pictures of each of the analysis regions A1, A2i, and A2ii into a software for image analysis and determining the pores 22 with predetermined conditions. At this time, the existence rate of the pores is calculated as a rate (Sh/Sa) of a total pore area Sh to an area Sa of the analysis region A. The pore size is obtained by converting an area of each of the pores 22 into a circle equivalent diameter. In the present embodiment, each of the pore rate and the pore size of the pores 22 is represented as an average of the at least 10 analysis regions A.

The multilayer piezoelectric element 2 according to the present embodiment is manufactured by any method and is, for example, manufactured by the following method.

First of all, a manufacturing step of the laminated body 4 is explained. In the manufacturing step of the laminated body 4, prepared are ceramic green sheets that will be the piezoelectric layers 10 after firing and a conductive paste that will be the internal electrode layers 16 and the dummy electrode layers 18 after firing.

For example, the ceramic green sheets are manufactured by the following manner. First of all, a raw material of a material constituting the piezoelectric layers 10 is mixed uniformly by wet mixing or so and is dried. Then, the raw material is calcined with appropriately determined conditions, and this calcined powder is pulverized in wet manner. The pulverized calcined powder is added with a binder and turned into a slurry. Moreover, the slurry is turned into a sheet by doctor blade method, screen printing method, or the like and is thereafter dried to obtain a ceramic green sheet. Incidentally, the raw material of the material constituting the piezoelectric layers 10 may contain inevitable impurities.

Next, an electrode paste containing a conductive material is applied onto the ceramic green sheet by printing method or so. This makes it possible to obtain green sheets where an internal electrode paste film and a dummy electrode paste film are formed in a predetermined pattern.

Next, the green sheets prepared in the above-mentioned procedure are laminated in a predetermined order. That is, the green sheets are laminated while the orientation of the electrode patterns 24a is changed as shown in FIG. 5. Only the ceramic green sheet is laminated on the top layer in the Z-axis direction constituting the front surface 4a of the laminated body 4 after firing.

Moreover, the laminated green sheets are pressurized for pressure bonding and are fired to obtain the laminated body 4 via necessary steps (e.g., drying step, debindering step). When the internal electrode layers 16 are composed of a noble metal (e.g., Ag—Pd alloy), the firing is preferably carried out at a furnace temperature of 800-1200° C. and atmospheric pressure. When the internal electrode layers 16 are composed of a base metal (e.g., Cu, Ni), the firing is preferably carried out at a furnace temperature of 800-1200° C. and an oxygen partial pressure of 1×10⁻⁷ to 1×10⁻⁹ MPa.

Most of the dummy-electrode pores 22b1 and the gap pores 22b2 are conceivably generated in the firing step. In particular, the gap pores 22b2 are conceivably mainly formed by a mutual pull of the piezoelectric layers 10 from the internal electrode layers 16 and the dummy electrode layers 18 in a volume shrinkage process of the electrode layers 16 and 18 in the firing step. Thus, the existence rate and the pore size of the pores 22 can be controlled by firing conditions. In particular, the heating rate, the holding time, and the hold temperature during firing are controlled for increasing the existence rate of the outer circumferential pores 22b compared to that of the central pores 22a.

When the amount of heat given to the laminated body 4 is increased by increasing the hold temperature in the firing step, the sintering becomes excessive, and the elements (e.g., Pb, Bi, K, Na) contained in the piezoelectric layers 10 are largely volatilized. Thus, many pores 22 are formed inside the laminated body 4. When the sintering becomes excessive, however, the volatilized elements escape from not only the outer circumferential part 14 but the central part of the laminated body 4, and piezoelectric characteristics tend to deteriorate. In the present embodiment, the heating rate is particularly lowered, and the existence rate (Ro) of the outer circumferential pores 22b thereby becomes high while preventing the generation of the central pores 22a.

Specifically, the heating rate during firing is normally about 300° C./h to 1500° C./h, but is 200° C./h or less in the present embodiment. When the heating rate is lower than normal one, the outer circumferential pores 22b are easily generated, and the existence rate (Ro) tends to be high. In the central part of the laminated body 4, however, it is possible to reduce pores and heighten the density. Preferably, the holding time during firing is 15 minutes to 240 minutes.

The laminated body 4 obtained through the sintering step is provided with the first external electrode 6 and the second external electrode 8 by sputtering, vapor deposition, plating, dip coating, or the like. The first external electrode 6 is formed on the front surface 4a and the lateral surface 4d of the laminated body 4, and the second external electrode 8 is formed on the front surface 4a and the lateral surface 4c of the laminated body 4. Incidentally, an insulation layer may be formed by applying an insulating resin onto the lateral surfaces 4d-4f of the laminated body 4 on which the external electrodes 6 and 8 are not formed.

Next, the multilayer piezoelectric element 2 with the external electrodes 6 and 8 is bonded on the vibration plate 30. In the present step, an adhesive material constituting the adhesive layer 32 is initially applied onto the vibration plate 30 and is thinly spread. After that, the multilayer piezoelectric element 2 is pushed and adhered to the vibration plate by pressing or so. At this time, the force pressing the element body is preferably applied to the central part of the laminated body 4.

Before or after the vibration plate is bonded, a polarization treatment is carried out for allowing the piezoelectric layers 10 to have piezoelectric activity. The polarization treatment is carried out by applying a DC electric field of 1-10 kV/mm to the first and second external electrodes 6 and 8 in an insulating oil of about 80-120 degrees. Incidentally, the DC electric field to be applied depends upon the material constituting the piezoelectric layers 10. Through such a process, the multilayer piezoelectric element 2 shown in FIG. 1 is obtained.

In the above process, the procedure for obtaining one multilayer piezoelectric element is shown, but actually used may be green sheets on which multiple electrode patterns 24 are formed on one sheet. An aggregate laminate formed using such sheets is appropriately cut before or after firing and thereby finally has the shape of the element as shown in FIG. 1.

In the multilayer piezoelectric element 2 according to the present embodiment, as mentioned above, Ro is higher than Rc, where Ro is an existence rate of the outer circumferential pores 22b existing in the outer circumferential part 14 of the internal electrode layer 16, and Rc is an existence rate of the central pores 22a existing in the central part of the laminated body 4. In this structure, the piezoelectric layers 10 can have elasticity and flexibility in the outer circumferential part 14 of the internal electrode layer 16. That is, the outer circumferential pores 22b conceivably reduce the inner stress and the difference in flexibility between the piezoelectric active parts 12 and the inactive parts in manufacturing or using the multilayer piezoelectric element 2. Thus, the multilayer piezoelectric element 2 according to the present embodiment can prevent the generation of cracks inside the laminated body 4 and does not have degraded characteristics.

Thus, the present embodiment can prevent the generation of cracks inside the laminated body 4 even if the piezoelectric layers 10 are thin, the lamination number of piezoelectric layers 10 is large, the lamination area of the laminated body 4 is wide and large, or the like. Due to the prevention of cracks, characteristics (e.g., displacement) are not degraded in the multilayer piezoelectric element 2 according to the present embodiment.

In the present embodiment, the vibration plate 30 is bonded to the multilayer piezoelectric element 2 for obtaining a large displacement. In such a use mode, the larger the element body becomes, the further the adhesion between the multilayer piezoelectric element 2 and the vibration plate 30 deteriorates. In particular, if bubble or excess adhesive component is present in the adhesive layer 32 between the multilayer piezoelectric element 2 and the vibration plate 30, the transmission of the vibration from the multilayer piezoelectric element 2 to the vibration plate 30 is disturbed, and it becomes difficult to obtain a large displacement.

In the multilayer piezoelectric element 2 according to the present embodiment, there are fewer pores in the central part of the laminated body 4, but there are many outer circumferential pores 22b in the outer circumferential part 14. In the bonding of the multilayer piezoelectric element 2 and the vibration plate 30, bubble or excess adhesive existing in the adhesive layer 32 thereby moves from the central part to the outer circumferential part of the laminated body 4 and is easily discharged from the adhesive layer 32. Thus, the multilayer piezoelectric element 2 according to the present embodiment can have a high adhesion with the vibration plate and can obtain a higher displacement.

Incidentally, a difference (Ro−Rc) between Ro and Rc is preferably 2% or more and 15% or less (more preferably, 3% or more and 8% or less). When the difference (Ro−Rc) is in the above range, it is possible to further improve characteristics (e.g., displacement) of the multilayer piezoelectric element 2 while preventing the generation of cracks.

In the multilayer piezoelectric element 2 according to the present embodiment, the gap pores 22b2 can prevent the composition of the piezoelectric layers 10 from changing. The reason may be as follows.

In the vicinity of the outer circumference of the laminated body 4 on which the dummy electrode layer 18 is laminated, volatile elements (e.g., Pb, Bi, K, Na) contained in the piezoelectric layers 10 are volatilized and discharged outside in the firing step. The dummy-electrode pores 22b1 are conceivably mainly generated in this volatile process, and the composition of the piezoelectric layers 10 slightly changes between the dummy electrode layers 18. However, the outer circumferential part 14 of the laminated body 4 does not contribute to the appearance of piezoelectric characteristics, and there is thereby no problem even if the composition slightly changes.

In the present embodiment, it is conceivable that the gap pores 22b2 stay the volatile elements inside the laminated body 4, and that the volatile elements are hard to escape from the piezoelectric active parts 12. Thus, the composition of the piezoelectric layers 10 is hard to change in the piezoelectric active parts 12, and the multilayer piezoelectric element 2 having a high piezoelectric constant is obtained.

In the present embodiment, the existence rate of the gap pores 22b2 is preferably 3% or more and 20% or less. When the existence rate of the pores in the gap 20 is in the above range, it is possible to further appropriately achieve both the prevention of cracks and the enhancement of piezoelectric characteristics.

As mentioned above, the gap pores 22b2 preferably have an average size of 0.04 μm or more and 0.18 μm or less. When the pores have such an average size, it is possible to further appropriately achieve both the prevention of cracks and the enhancement of piezoelectric characteristics.

In the present embodiment, the gap 20 preferably has a width W3 of 0.05 mm or more and 0.2 mm or less. When the gap 20 has a width W3 in the above range, the region where the gap pores 22b2 are present is in an appropriate range, and the generation of cracks can further be reduced.

In the present embodiment, there is no limit to the thickness and the lamination number of the piezoelectric layers 10 or the size of the laminated body 4, but the following case is effectively applicable. If the piezoelectric layers 10 are thin, the laminated body is easily deformable, and cracks are easily generated. In the present embodiment, however, the generation of cracks can be prevented by the above-mentioned effect even if the piezoelectric layers 10 have a thickness of 1-50 μm. Likewise, the generation of cracks can be prevented by the above-mentioned effect even if the lamination number of piezoelectric layers 10 is large (e.g., 3-20 layers).

The larger the area of the piezoelectric layers 10 is, the more easily the bubble or the excess adhesive material is present in the bonding to the vibration plate 30. In the present embodiment, however, even if the piezoelectric layers 10 have a large area of 100 (Wx) mm×100 (Wy) mm or more, it is possible to enhance the adhesion between the multilayer piezoelectric element 2 and the vibration plate 30 and to obtain a high displacement. In addition, the generation of cracks can also be prevented.

### Second Embodiment

Hereinafter, Second Embodiment of the present invention is explained FIG. 3B, FIG. 4B, and FIG. 7B. Incidentally, the common features between First Embodiment and Second Embodiment are not explained and are provided with the same references.

FIG. 3B is a schematic view of a Y-Z cross section of a multilayer piezoelectric element 3 according to Second Embodiment. FIG. 4B is a plane view of an electrode pattern 24b of the multilayer piezoelectric element 3. In the multilayer piezoelectric element 3, unlike First Embodiment, no dummy electrode layer 18 is formed in the outer circumference of the internal electrode layer 16 as shown in FIG. 3B and FIG. 4B. Thus, only the piezoelectric layer 10 is laminated in the outer circumferential part 14 of the internal electrode layer 16.

In such a multilayer structure, the size of the internal electrode layer 16 (W1×W2) is preferably about 0.90 times to 0.98 times larger than the size of the piezoelectric layer (Wx×Wy). In such a range, it is possible to have a region where the outer circumferential pores are generated and to securely have a region of the piezoelectric active parts 12.

In the multilayer piezoelectric element 3 according to Second Embodiment, multiple pores 22 are also formed inside the laminated body 4. In terms of the central pores 22a existing in the central part of the laminated body 4, the formation process and the existence rate (Rc) are common with those of First Embodiment and are observed in the embodiment of FIG. 6.

On the other hand, as shown in FIG. 7B, outer circumferential pores 22c are formed in the outer circumferential part 14 of the internal electrode layer 16. The formation process of the outer circumferential pores 22c is common with that of the outer circumferential pores 22b1 according to First Embodiment. The outer circumferential pores 22c are conceivably formed by the emission of volatile elements of Pb, Bi, K, Na, etc. contained in the piezoelectric layers 10 to the outside of the laminated body 4 during firing. Thus, more outer circumferential pores 22c are present in a closer position to the outer surface of the laminated body 4, and fewer outer circumferential pores 22c are present in a closer position to the internal electrode layer 16. Incidentally, the existence rate Rc (Ro) of the pores according to Second Embodiment is determined similarly to First Embodiment.

In Second Embodiment, the existence rate Ro of the outer circumferential pores 22c is also higher than the existence rate Rc of the central pores 22a, and effects similar to those of First Embodiment are demonstrated. In Second Embodiment, however, no dummy electrode layers 18 are present, and piezoelectric characteristics of the multilayer piezoelectric element 2 according to First Embodiment thereby tend to be higher than those of the multilayer piezoelectric element 3 according to the present embodiment. This is probably because the volatile elements of the piezoelectric active parts 12 according to Second Embodiment more easily flow to the outside of the laminated body 4 compared to the multilayer piezoelectric element 2 according to First Embodiment.

The present invention is explained based on the embodiments shown in the figures, but is not limited to the above-mentioned embodiments and can variously be changed within the scope of the present invention. For example, the multilayer piezoelectric element 2 (3) has a substantially rectangular plan-view shape in the above-mentioned embodiments, but may have any other plan-view shape of circle, ellipse, polygon, etc. This is also the case with the vibration plate 30, and the vibration plate 30 may have a plan-view shape of circle, ellipse, polygon, etc. The electrode pattern 24a shown in FIG. 4A and the electrode pattern 24b failing to have the dummy electrode layer 18 shown in FIG. 4B may be laminated alternately.

As mentioned above, the internal electrode layers 16 and the dummy electrode layers 18 may be composed of different materials, and the thermal shrinkage start temperature of the material constituting the dummy electrode layers 18 may be higher than that of the internal electrode layers 16. Since the internal electrode layers 16 and the dummy electrode layers 18 are composed in such a manner, the gap pores 22b2 are easily formed. When the internal electrode layers 16 and the dummy electrode layers 18 are composed of different materials, an optimal range of the width W3 of the gap 20 is larger compared to when they are composed of the same material. This optimal range can be 0.03 mm or more and 0.6 mm or less (preferably, 0.05 mm or more and 0.3 mm or less).

The multilayer piezoelectric element according to the present invention can be utilized as a conversion element from electrical energy to mechanical energy. For example, the multilayer piezoelectric element according to the present invention is applicable to piezoelectric actuators, piezoelectric buzzers, piezoelectric sounders, ultrasonic motors, speakers, etc. and is particularly favorably utilized as piezoelectric actuators. Specifically, the piezoelectric actuators are utilized for haptic devices, lens driving, HDD head driving, inkjet printer head driving, fuel injection valve driving, etc.

### EXAMPLES

Hereinafter, the present invention is explained based on further detailed examples, but is not limited thereto.

### (Experiment 1)

First of all, predetermined amounts of chemically pure main-component raw material and sub-component raw material were weighed so that piezoelectric layers would be composed of PZT based ceramics, and the raw materials were mixed in wet manner in a ball mill. After the mixing, the mixture was calcined at 800° C.−900° C. and pulverized again in the ball mill. The calcined powder thus obtained was added with a binder and turned into a slurry. The slurry was turned into a sheet by screen printing method and thereafter dried to obtain ceramic green sheets.

Next, a conductive paste whose main component was an Ag—Pd alloy was applied onto the ceramic green sheets by printing method. Incidentally, an electrode pattern 24b shown in FIG. 4B was printed without forming dummy electrode layers in Examples 1 and 2.

After the green sheets thus obtained were laminated by nine or more layers in a predetermined order, the laminated green sheets were pressed to be bonded and were dried and debindered. Then, this pre-fired laminated body was fired at a heating rate of 200° C./h or lower in the atmospheric pressure atmosphere. Table 1 shows detailed firing conditions of each Example. In Examples 1 and 2, pores were formed in the outer circumferential part of the internal electrode layer by firing for a long time at a lower heating rate than before.

Incidentally, the fired laminated bodies of Experiment 1 had a substantially rectangular parallelepiped shape of width (Wx) 30 mm×length (Wy) 30 mm×thickness 0.1 mm. The thickness of the piezoelectric layers was 10 μm on average. The thickness of the internal electrode layers was 1 μm on average. The laminated bodies thus manufactured were provided with a pair of external electrodes and were polarized, and samples of multilayer piezoelectric elements were thereby manufactured. In each Example, 1000 samples were manufactured and subjected to the following evaluation.

### Examples 3-14

In Examples 3-14, a dummy electrode layer was formed with a gap in an outer circumferential part of the internal electrode layer. The dummy electrode layer was an Ag—Pd alloy whose composition was the same as that of the internal electrode layer. Incidentally, the gap width W3 was 0.2 mm on average in Examples 3-10, and the samples of laminated bodies were manufactured by changing the standard in Examples 11-14.

In each of Examples 3-10, samples of laminated bodies were manufactured by changing the standard of firing conditions. In particular, the holding time was changed in each of Examples 3-5 with the common heating rate (200° C./h) and holding temperature (1000° C.). The holding time was changed in each of Examples 6-8 with the heating rate (100° C./h), which was slower than that of Examples 3-5. The holding temperature was changed in Examples 9 and 10. Table 1 shows detailed firing conditions of each Example.

Except for the above-mentioned features, Examples 3-14 were common with Examples 1 and 2 and evaluated similarly.

### Comparative Example 1

In Comparative Example 1, no dummy electrodes were formed similarly to Example 1, but firing conditions were changed. Specifically, samples of laminated bodies were manufactured with a higher heating rate (1500° C./h) and a shorter holding time (15 min) compared to those of Example 1. Except for the above-mentioned features, Comparative Example 1 was common with Example 1 and evaluated similarly.

### Comparative Example 2

In Comparative Example 2, dummy electrode layers were formed similarly to Example 3, but samples of laminated bodies were manufactured with a higher heating rate during firing (1500° C./h) compared to that of Example 3. Except for the above-mentioned features, Comparative Example 2 was common with Example 3 and evaluated similarly.

### Comparative Example 3

In Comparative Example 3, samples of laminated bodies were manufactured similarly to Comparative Example 1, and pores were hardly formed in the laminated body. In Comparative Example 3, however, pores were formed in the external electrodes by containing burned particles in the raw material of the external electrodes in the formation of the external electrodes. In Comparative Example 3, the existence rate of the pores in the external electrodes was 8%, and the average size of the pores was 133 nm.

### (Evaluation)

### Evaluation of Pores

As mentioned above, cross-sectional pictures of the analysis regions A1-A3 shown in FIG. 6 to FIG. 7B were taken by FE-SEM. The existence rate and the size of the pores in each of the regions were measured by analyzing the cross-sectional pictures with an image analysis type particle size distribution measurement software (Mac-View).

### Evaluation of Cracks

Cracks were evaluated by observing cross sections of the manufactured samples of laminated bodies by FE-SEM. Specifically, a crack incidence was calculated in the following manner. First of all, 100 samples were selected at random from 1000 samples of laminated bodies and fixed on a resin, and a cross section of each of the 100 samples underwent a mirror polishing. Then, a crack incidence was calculated by counting the number of samples having a crack of the piezoelectric layers, a peeling between the piezoelectric layers and the electrode layers, or the like in the observation of the cross section of each sample. In terms of the crack incidence, 10% or less was considered to be favorable.

### Measurement of Piezoelectric Constant d_{B}

A piezoelectric constant d₃₃ (piezoelectric output constant) of each comparative example and each example was measured by Berlincourt method using a d₃₃ meter. The piezoelectric constant d₃₃ was calculated by measuring an electric charge generated in the element body in application of vibration to the piezoelectric element. When the main component of the piezoelectric layers was PZT, a piezoelectric constant d₃₃ of 400×10⁻¹² C/N or more was considered to be favorable.

### Evaluation of Displacement

Before the evaluation of displacement, samples of multilayer piezoelectric elements of each Example were initially bonded on a vibration plate composed of Ni—Fe alloy using an adhesive (WORLD LOCK 830 manufactured by Kyoritsu Chemical & Co., Ltd.). The size of the vibration plate was 80 mm×60 mm. The application amount of the adhesive was controlled to be the same in all Examples and Comparative Examples. The samples of vibration devices thus obtained were placed on a digimicro manufactured by NIKON CORPORATION and measured for displacement amount at 12V application. Incidentally, the displacement amount was measured for 10 samples in each of Examples and Comparative Examples, and this average is shown in Table 1. When the main component of the piezoelectric layers was PZT, a displacement amount of 30 μm or more was considered to be favorable as the vibration devices.

TABLE 1

| | | | | | | Pores in Laminated Body | | |
|---|---|---|---|---|---|---|---|---|
| | | | | | | | Outer | |
| | | | | | | Central | Circumferential | |
| | Presence of | | Firing Conditions | | | Pores | Pores | |
| | Dummy | Gap | Heating | Holding | Holding | Existence | Existence | Difference in |
| Sample | Electrode | Width | Rate | Time | Temperature | Rate | Rate | Existence Rate |
| No. | Layers | mm | ° C./h | min | ° C. | Rc (%) | Ro (%) | Ro − Rc (%) |
| Comp. | no | — | 1500 | 15 | 1000 | 1 | 1 | 0 |
| Ex. 1 | | | | | | | | |
| Comp. | yes | 0.2 | 1500 | 15 | 1000 | 1 | 2 | 1 |
| Ex. 2 | | | | | | | | |
| Comp. | no | — | 1500 | 15 | 1000 | 1 | 2 | 1 |
| Ex. 3※ | | | | | | | | |
| Ex. 1 | no | — | 200 | 60 | 950 | 1 | 14 | 13 |
| Ex. 2 | no | — | 200 | 120 | 950 | 1 | 16 | 15 |
| Ex. 3 | yes | 0.2 | 200 | 15 | 1000 | 1 | 4 | 3 |
| Ex. 4 | yes | 0.2 | 200 | 120 | 1000 | 2 | 8 | 6 |
| Ex. 5 | yes | 0.2 | 200 | 240 | 1000 | 4 | 8 | 4 |
| Ex. 6 | yes | 0.2 | 100 | 15 | 1000 | 5 | 9 | 4 |
| Ex. 7 | yes | 0.2 | 100 | 120 | 1000 | 6 | 14 | 8 |
| Ex. 8 | yes | 0.2 | 100 | 240 | 1000 | 8 | 17 | 9 |
| Ex. 9 | yes | 0.2 | 200 | 120 | 950 | 3 | 5 | 2 |
| Ex. 4 | yes | 0.2 | 200 | 120 | 1000 | 2 | 8 | 6 |
| Ex. 10 | yes | 0.2 | 200 | 120 | 1050 | 7 | 15 | 8 |
| Ex. 11 | yes | 0.03 | 200 | 120 | 1000 | 3 | 7 | 4 |
| Ex. 12 | yes | 0.05 | 200 | 120 | 1000 | 2 | 7 | 5 |
| Ex. 13 | yes | 0.1 | 200 | 120 | 1000 | 4 | 8 | 4 |
| Ex. 4 | yes | 0.2 | 200 | 120 | 1000 | 2 | 8 | 6 |
| Ex. 14 | yes | 0.3 | 200 | 120 | 1000 | 2 | 8 | 6 |

| | | | Characteristics | | |
|---|---|---|---|---|---|
| | | | | | Displacement |
| | Pores in Gap | | | Piezoelectric | (with |
| | Existence | Pore | Crack | Constant | Vibration |
| Sample | Rate | Size | Incidence | d₃₃ | Plate) |
| No. | % | nm | % | ×10⁻¹² C/N | μm |
| Comp. | — | — | 37 | 387 | 27 |
| Ex. 1 | | | | | |
| Comp. | 0 | 0 | 22 | 395 | 28 |
| Ex. 2 | | | | | |
| Comp. | — | — | 5 | 380 | 29 |
| Ex. 3※ | | | | | |
| Ex. 1 | — | — | 5 | 377 | 34 |
| Ex. 2 | — | — | 4 | 353 | 33 |
| Ex. 3 | 3 | 45 | 5 | 447 | 41 |
| Ex. 4 | 8 | 82 | 3 | 476 | 45 |
| Ex. 5 | 16 | 154 | 0 | 482 | 47 |
| Ex. 6 | 5 | 72 | 2 | 432 | 40 |
| Ex. 7 | 17 | 169 | 2 | 429 | 39 |
| Ex. 8 | 24 | 232 | 2 | 401 | 35 |
| Ex. 9 | 6 | 78 | 3 | 415 | 36 |
| Ex. 4 | 8 | 82 | 3 | 476 | 45 |
| Ex. 10 | 19 | 183 | 5 | 421 | 39 |
| Ex. 11 | 2 | 32 | 10 | 472 | 44 |
| Ex. 12 | 8 | 93 | 5 | 479 | 46 |
| Ex. 13 | 10 | 101 | 3 | 472 | 46 |
| Ex. 4 | 8 | 82 | 3 | 476 | 45 |
| Ex. 14 | 3 | 52 | 7 | 470 | 45 |

As shown in Table 1, Comparative Examples 1-3 were fired at a high heating rate for a short holding time as before. Thus, in Comparative Examples 1-3, pores were hardly formed in the laminated body, and there was almost no difference in existence rate between the central pores and the outer circumferential pores. As a result, in Comparative Examples 1 and 2, the crack incidence was high, and the piezoelectric constant d₃₃ and the displacement amount failed to satisfy each standard value. In Comparative Example 3, the generation of cracks was prevented to some degree by the pores formed in the external electrodes, but the piezoelectric constant d₃₃ and the displacement amount failed to satisfy each standard value.

On the other hand, in Examples 1-14 of the present invention, the existence rate of the pores in the laminated body was higher than that of Comparative Examples. In all Examples, the existence rate Ro of the outer circumferential pores was higher than the existence rate Rc of the central pores. As a result, in Examples 1-14, the crack incidence was restrained to 10% or less, and the displacement amount was large (30 μm or more). Thus, the superiority of forming the pores in the laminated body (particularly, the outer circumferential pores) was confirmed.

Comparing Examples, the piezoelectric constant d₃₃ of Examples 3-14 (dummy electrode layers were formed) was higher than that of Examples 1 and 2 and satisfied the standard value. As a result, it was confirmed that forming the pores in the gap can prevent the outflow of the volatize elements and achieve a high piezoelectric constant d₃₃. In Comparative Example 2, the dummy electrode layers were formed, but no pores were formed in the gap. Thus, Comparative Example 2 could not prevent the discharge of the volatilized elements and had a low piezoelectric constant d₃₃.

In Examples 3-7 and 10-14 (the difference (Ro−Rc) between the existence rate Ro of the outer circumferential pores and the existence rate Rc of the central pores was 3%-8%) of Examples 1-14, the displacement amount was large (39 μm or more). As a result, it was confirmed that the difference in existence rate ((Ro−Rc) falling in the above range can further improve displacement characteristics.

Next, the relation between the firing conditions and the existence rate of the pores is examined. In comparison between Examples 3-5 and Examples 6-8, the existence rates of the central pores and the outer circumferential pores tended to be high by lowering the heating rate. A similar tendency can be confirmed for the holding time. That is, the longer the holding time was, the higher the existence rates of the pores were. Comparing Examples 4, 9, and 10, the higher the holding temperature was, the higher the existence rates of the pores tended to be. Based on the above results, it was confirmed that desired pores were formed in the laminated body by controlling respective firing conditions provided that the heating rate was 200° C./h or less.

Incidentally, a tendency similar to the above can also be confirmed for the pores in the gap. That is, the lower the heating rate was, the longer the holding time was, or the higher the holding temperature was, the higher the existence rate tended to be, and the larger the pore size tended to be. In the examination of the relation between the firing conditions and the existence rate of the pores, it was confirmed that when the existence rate in the gap was 3%-20%, both the prevention of cracks and the retainment of favorable piezoelectric characteristics can be achieved. As for the relation between the average size of the pores in the gap and characteristics, it was similarly confirmed that when the pore size was 40 nm or more and 180 nm or less, both the prevention of cracks and the retainment of favorable piezoelectric characteristics can be achieved.

In Example 11, since the existence rate in the gap and the pore size were lower than the above-mentioned lower limits, the crack incidence was higher compared to that of the other examples. In Example 8, since the existence rate in the gap and the pore size were higher than the above-mentioned higher limits, the outflow amount of the volatile elements was large, and the piezoelectric constant d₃₃ was lower than that of the other examples. As a result, it was confirmed that it is effective to control the existence rate in the gap and the pore size within predetermined ranges.

In the examination of the relation between the gap width W3 and characteristics according to Examples 4 and 11-14, it was confirmed that when the gap width W3 was 0.05 mm or more and 0.2 mm or less, the crack incidence was restrained to 5% or less. On the other hand, the crack incidence of Example 11 (the gap width W3 was small) was higher than that of the other examples. This is probably because when the gap width W3 was small, the region where pores were present was small, and the crack prevention effect by the pores was weakened.

In Example 14 (the gap width W3 was large), it was also confirmed that the larger the gap width W3 was, the higher the crack incidence tended to be. When the gap width is large, it is conceivably hard to form pores in the piezoelectric layers.

### (Experiment 2)

In Experiment 2, samples of multilayer piezoelectric elements were manufactured by changing the composition of the piezoelectric layers or the dummy electrode layers.

In Examples 21 and 22, the material constituting the piezoelectric layers was changed. In Example 21, bismuth ferrate-barium titanate (BFO-BT) was used. In Example 22, potassium sodium niobite (KNN) was used. The manufacturing conditions of Examples 21 and 22 were common with those of Example 4 according to Experiment 1, but the holding temperature during firing was changed due to the change of the material of the piezoelectric layers. In Experiment 2, a similar evaluation to Experiment 1 was carried out, but when BFO-BT was used, the standard value of the piezoelectric constant d₃₃ was 200×10⁻¹² C/N or more, and the standard value of the displacement amount was 20 μm or more. Likewise, when KNN was used, the standard value of the piezoelectric constant d₃₃ was 250×10⁻¹² C/N or more, and the standard value of the displacement amount was 20 μm or more.

In Examples 24, the dummy electrode layers were composed of an Ag—Pd alloy whose composition was different from that of the internal electrode layers. Specifically, the composition of the internal electrode layers was Ag90 wt %-Pd10 wt %, and the composition of the dummy electrode layers was Ag80 wt %-Pd20 wt % (the ratio of Pd was increased). Incidentally, Example 23 was an example for comparison with Example 24 and had the same composition between the internal electrode layers and the dummy electrode layers. Table 2 shows the evaluation results of characteristics or so of Examples according to Experiment 2.

### Comparative Examples 21 and 22

Comparative Examples 21 and 22 were comparative examples corresponding to Examples 21 and 22. In Comparative Examples 21 and 22, the piezoelectric layers were formed using BFO-BT or KNN. In Comparative Examples 21 and 22, however, no dummy electrode layers were formed, and the firing was carried out at a high heating rate for a short holding time as before. Except for the above features, Comparative Examples 21 and 22 were common with Examples 21 and 22. Table 2 shows the evaluation results.

TABLE 2

| | | | | | | | | Pores in |
|---|---|---|---|---|---|---|---|---|
| | | | | | | | | Laminated Body |
| | | | | | Firing Conditions | | | Central |
| | Composition of Each Layer | | | | | | Holding | Pores |
| | | Internal | Dummy | Gap | Heating | Holding | Temper- | Existence |
| Sample | Piezoelectric | Electrode | Electrode | Width | Rate | Time | ature | Rate |
| No. | Layers | Layers | Layers | mm | ° C./h | min | ° C. | Rc (%) |
| Comp. | BFO-BT | Ag90-Pd10 | — | — | 1500 | 15 | 930 | 1 |
| Ex. 21 | | | | | | | | |
| Comp. | KNN | Ag90-Pd10 | — | — | 1500 | 15 | 1030 | 2 |
| Ex. 22 | | | | | | | | |
| Ex. 21 | BFO-BT | Ag90-Pd10 | Ag90-Pd10 | 0.2 | 200 | 120 | 930 | 4 |
| Ex. 22 | KNN | Ag90-Pd10 | Ag90-Pd10 | 0.2 | 200 | 120 | 1030 | 5 |
| Ex. 23 | PZT | Ag90-Pd10 | Ag90-Pd10 | 0.2 | 100 | 15 | 950 | 5 |
| Ex. 24 | PZT | Ag90-Pd10 | Ag80-Pd20 | 0.2 | 100 | 15 | 950 | 5 |

| | Pores in Laminated Body | | | | | | |
|---|---|---|---|---|---|---|---|
| | Outer | | | | Characteristics | | |
| | Circumferential | | | | | | Displacement |
| | Pores | | Pores in Gap | | | Piezoelectric | (with |
| | Existence | Difference in | Existence | Pore | Crack | Constant | Vibration |
| Sample | Rate | Existence Rate | Rate | Size | Incidence | d₃₃ | Plate) |
| No. | Ro (%) | Ro − Rc (%) | % | nm | % | ×10⁻¹² C/N | μm |
| Comp. | 2 | 1 | — | — | 31 | 181 | 17 |
| Ex. 21 | | | | | | | |
| Comp. | 2 | 0 | — | — | 38 | 244 | 19 |
| Ex. 22 | | | | | | | |
| Ex. 21 | 7 | 3 | 9 | 98 | 4 | 230 | 22 |
| Ex. 22 | 9 | 4 | 11 | 112 | 4 | 281 | 25 |
| Ex. 23 | 9 | 4 | 5 | 72 | 2 | 432 | 40 |
| Ex. 24 | 8 | 3 | 18 | 165 | 3 | 457 | 42 |

As shown in Table 2, in Comparative Examples 21 and 22, pores were hardly formed in the laminated body, and there was almost no difference in existence rate between the central pores and the outer circumferential pores. As a result, in Comparative Examples 21 and 22, the crack incidence was high, and both of the piezoelectric constant d₃₃ and the displacement amount failed to satisfy the standard value.

On the other hand, in Examples 21 and 22, the existence rate of the pores in the laminated body was higher than that of Comparative Examples 21 and 22, and the existence rate Ro of the outer circumferential pores was higher than the existence rate Rc of the central pores. As a result, the crack incidence of Examples 21 and 22 was restrained to 10% or less. In addition, both of the piezoelectric constant d₃₃ and the displacement amount of Examples 21 and 22 satisfied the standard value. As a result, it was confirmed that even if the composition of the piezoelectric layers is changed, the generation of cracks can be prevented, and a multilayer piezoelectric element having excellent piezoelectric characteristics can be obtained.

Comparing Examples 23 and 24, the existence rate of pores in the gap of Example 24 (the composition of the dummy electrode layers was changed) was higher than that of Example 23, and the pore size of Example 24 was also larger than that of Example 23. This is probably because changing the composition between the internal electrode layers and the dummy electrode layers generated a difference in force where the electrode layers pull the piezoelectric layers, and the pores were easily formed in the gap. Incidentally, both of Examples 23 and 24 sufficiently prevented the generation of cracks and satisfied the standard value of the piezoelectric constant d₃₃ and the standard value of the displacement amount. Thus, it was confirmed that even if the dummy electrode layers are composed of a different material, similar effects to those in case of the same material are demonstrated.

### DESCRIPTION OF THE REFERENCE NUMERICAL

2, 3 . . . multilayer piezoelectric element
4 . . . laminated body
   4a . . . front surface of laminated body
   4b . . . back surface of laminated body
   4c-4f . . . lateral surface of laminated body
6 . . . first external electrode
   6a . . . first lateral part
   6b . . . first surface part
8 . . . second external electrode
   8a . . . second lateral part
   8b . . . second surface part
10 . . . piezoelectric layer
12 . . . piezoelectric active part
14 . . . outer circumferential part
16 . . . internal electrode layer
   16a . . . leading portion
18 . . . dummy electrode layer
   18a, 18b . . . lateral pattern
   18c . . . joint pattern
20 . . . gap
22 . . . pore
   22a . . . central pore
   22b, 22c . . . outer circumferential pore
      22b1 . . . dummy-electrode pore
      22b2 . . . gap pore
24a, 24b . . . electrode pattern
4c1-4f1 . . . side
30 . . . vibration plate
32 . . . adhesive layer

What is claimed is:

1. A multilayer piezoelectric element comprising:
a laminated body including:
a piezoelectric layer formed along a plane including a first axis and a second axis perpendicular to each other; and
an internal electrode layer laminated on the piezoelectric layer; and
a lateral electrode formed on a lateral surface of the laminated body perpendicular to the first axis,
wherein the internal electrode layer has a leading portion exposed to the lateral surface of the laminated body and is electrically connected with the lateral electrode via the leading portion, and
wherein Ro is higher than Rc in the the laminated body, in which Ro is an existence rate of outer circumferential pores existing in the piezoelectric layer located in an outer circumferential part of the internal electrode layer, and Rc is an existence rate of central pores existing in a central part of the laminated body.

2. The multilayer piezoelectric element according to claim 1, wherein a difference (Ro−Rc) between Ro and Rc is 2% or more and 15% or less in the laminated body.

3. The multilayer piezoelectric element according to claim 1, wherein a difference (Ro−Rc) between Ro and Rc is 3% or more and 8% or less in the laminated body.

4. The multilayer piezoelectric element according to claim 1, wherein a dummy electrode layer is formed with a gap to surround the outer circumferential part of the internal electrode layer excluding the leading portion on the plane of the piezoelectric layer.

5. The multilayer piezoelectric element according to claim 4, wherein gap pores are formed in the piezoelectric layer located in the gap between the internal electrode layer and the dummy electrode layer in the laminated body.

6. The multilayer piezoelectric element according to claim 5, wherein an existence rate of the gap pores in the piezoelectric layer located in the gap is 3% or more and 20% or less.

7. The multilayer piezoelectric element according to claim 4, wherein the gap has a width of 0.05 mm or more and 0.2 mm or less.

8. The multilayer piezoelectric element according to claim 5, wherein the gap has a width of 0.05 mm or more and 0.2 mm or less.

9. The multilayer piezoelectric element according to claim 6, wherein the gap has a width of 0.05 mm or more and 0.2 mm or less.

10. The multilayer piezoelectric element according to claim 5, wherein the gap pores have an average size of 0.04 μm or more and 0.18 μm or less.

11. The multilayer piezoelectric element according to claim 6, wherein the gap pores have an average size of 0.04 μm or more and 0.18 μm or less.

12. The multilayer piezoelectric element according to claim 7, wherein the gap pores have an average size of 0.04 μm or more and 0.18 μm or less.
